(19) United States
(12) Patent Application Publication
(10) Pub. No.: US 2026/0100338 A1
(43) Pub. Date: Apr. 9, 2026

(54) BELLOWS SEAL FOR LOW THRU-FORCE ACTUATION OF TEMPERATURE PROBE ACROSS VACUUM INTERFACE

(71) Applicant: LAM RESEARCH CORPORATION, Fremont, CA (US)

(72) Inventors: Aris PEREZ, Fremont, CA (US); Scott STEVENOT, Pleasanton, CA (US); Alexander MATYUSHKIN, San Jose, CA (US); Adam Christopher MACE, Morgan Hill, CA (US)

(21) Appl. No.: 19/113,521

(22) PCT Filed: Sep. 18, 2023
(86) PCT No.: PCT/US2023/032982

§ 371 Date: Mar. 20, 2025

Related U.S. Application Data
(60) Provisional application No. 63/409,422, filed on Sep. 23, 2022.

(51) Int. Cl. H01J 37/32

(52) U.S. Cl. CPC H01J 37/32513; H01J 37/32642; H01J 37/32724

(57) ABSTRACT

An actuator assembly to actuate a plasma tuning ring in a processing chamber includes an actuator, a rod, bellows, and vacuum seals. The actuator is arranged external to the processing chamber. The processing chamber is under vacuum. The actuator is at atmospheric pressure. The rod is coupled to the actuator and to the plasma tuning ring in the processing chamber. The bellows are arranged external to the processing chamber between the actuator and the processing chamber. The rod passes through the bellows into the processing chamber. The vacuum seals are disposed between the bellows and the actuator and between the bellows and the processing chamber to seal the vacuum in the processing chamber from the atmospheric pressure external to the processing chamber.

### CROSS-REFERENCE TO RELATED APPLICATIONS

This application claims the benefit of U.S. Provisional Application No. 63/409,422, filed on Sep. 23, 2022. The entire disclosure of the above application is incorporated herein by reference.

### FIELD

The present disclosure relates generally to substrate processing systems and more particularly to a bellows seal for low thru-force actuation of a temperature probe across a vacuum interface.

### BACKGROUND

The background description provided here is for the purpose of generally presenting the context of the disclosure. Work of the presently named inventors, to the extent it is described in this background section, as well as aspects of the description that may not otherwise qualify as prior art at the time of filing, are neither expressly nor impliedly admitted as prior art against the present disclosure.

Plasma etch processes are performed on substrates in processing chambers typically under vacuum. In a processing chamber, a top edge ring (TER) surrounds a substrate arranged on a substrate support. The TER is moved in and out of the processing chamber by a robot. A tunable edge sheath (TES) ring is arranged under the TER. The TES ring comprises an electrode that couples radio frequency (RF) power to the TER to adjust the shape of plasma near the edge of the substrate. The RF power can be adjusted to improve etch uniformity on the substrate. Since the TES ring is used to adjust the shape of the plasma near the edge of the substrate, the TES ring may also be generally called a plasma tuning ring.

### SUMMARY

An actuator assembly to actuate a plasma tuning ring in a processing chamber comprises an actuator, a rod, bellows, and vacuum seals. The actuator is arranged external to the processing chamber. The processing chamber is under vacuum. The actuator is at atmospheric pressure. The rod is coupled to the actuator and to the plasma tuning ring in the processing chamber. The bellows are arranged external to the processing chamber between the actuator and the processing chamber. The rod passes through the bellows into the processing chamber. The vacuum seals are disposed between the bellows and the actuator and between the bellows and the processing chamber to seal the vacuum in the processing chamber from the atmospheric pressure external to the processing chamber.

In additional feature, the bellows comprise a polymer.

In additional feature, the vacuum seals do not obstruct movement of the rod through the bellows.

In additional feature, the vacuum seals comprise O-rings.

In additional features, a system comprises the actuator assembly and further comprises a substrate support, an edge ring, and a temperature sensing assembly. The substrate support is arranged in the processing chamber to support a substrate. The plasma tuning ring is arranged in the substrate support. The edge ring is arranged proximate to the plasma tuning ring and around the substrate during substrate processing. The temperature sensing assembly is configured to sense temperature of the edge ring. The temperature sensing assembly comprises a spring assembly, second bellows, and a temperature probe. The spring assembly is arranged external to the processing chamber. The second bellows are arranged external to the processing chamber between the spring assembly and the processing chamber. The temperature probe is coupled to the spring assembly. The temperature probe passes through the second bellows and the plasma tuning ring. The spring assembly maintains contact between the temperature probe and the edge ring.

In additional feature, the second bellows comprise a polymer.

In additional feature, the system further comprises second vacuum seals disposed between the second bellows and the spring assembly and between the second bellows and the processing chamber to seal the vacuum in the processing chamber.

In additional feature, the second vacuum seals do not obstruct movement of the temperature probe through the second bellows.

In additional feature, the second vacuum seals comprise O-rings.

In additional feature, the actuator is configured to move the plasma tuning ring away from the edge ring when the edge ring clamps to the substrate support.

In additional feature, the actuator is configured to move the plasma tuning ring to contact the edge ring after the edge ring is clamped to the substrate support.

In additional feature, the temperature probe moves with the plasma tuning ring when the actuator actuates the plasma tuning ring.

In additional feature, the plasma tuning ring comprises an electrode to supply radio frequency power to the edge ring. The actuator is configured to move the plasma tuning ring to maintain coupling between the plasma tuning ring and the edge ring during substrate processing.

In additional features, the temperature probe comprises a temperature sensor attached to an end of the temperature probe that is proximate to the plasma tuning ring. The spring assembly is configured to maintain contact between the temperature sensor and the edge ring.

In additional features, the plasma tuning ring comprises an electrode to supply radio frequency power to the edge ring. The temperature probe passes through the electrode to contact the edge ring.

In additional features, the spring assembly comprises a spring and a sealant. The spring is disposed around a holder. The temperature probe passes through the holder. The sealant is disposed around the temperature probe. The sealant extends from the holder through the second bellows, the substrate support, and the plasma tuning ring to seal the vacuum in the processing chamber.

In additional feature, the sealant comprises an epoxy material.

In additional feature, the temperature sensing assembly further comprises a second seal disposed around the temperature probe in the plasma tuning ring to prevent erosion of the temperature probe and the sealant.

In additional feature, the second seal comprises an O-ring.

In still other features, a system comprises a substrate support, an edge ring, a plasma tuning ring, and an actuator assembly. The substrate support is arranged in a processing chamber under vacuum to support a substrate. The edge ring is arranged around the substrate on the substrate support. The plasma tuning ring is arranged adjacent to the edge ring in the substrate support. The actuator assembly is configured to actuate the plasma tuning ring. The actuator assembly comprises an actuator, a rod, bellows, and vacuum seals. The actuator is coupled externally to the processing chamber. The actuator is at atmospheric pressure. The rod is coupled to the actuator and to the plasma tuning ring. The bellows are arranged externally to the processing chamber between the actuator and the processing chamber. The rod passes through the bellows. The vacuum seals are disposed between the bellows and the actuator and between the bellows and the processing chamber to seal the vacuum in the processing chamber from the atmospheric pressure external to the processing chamber.

In additional feature, the vacuum seals do not obstruct movement of the rod through the bellows.

In additional features, the system further comprises a temperature sensing assembly comprising a spring assembly, second bellows, and a temperature probe. The spring assembly is coupled externally to the processing chamber. The second bellows are arranged externally to the processing chamber between the spring assembly and the processing chamber. The temperature probe is coupled to the spring assembly. The temperature probe passes through the second bellows and the plasma tuning ring. The spring assembly maintains contact between the temperature probe and the edge ring.

In additional feature, system further comprises second vacuum seals disposed between the second bellows and the spring assembly and between the second bellows and the processing chamber to seal the vacuum in the processing chamber.

In additional feature, the second vacuum seals do not obstruct movement of the temperature probe through the second bellows.

In additional feature, the actuator is configured to move the plasma tuning ring away from the edge ring when the edge ring clamps to the substrate support.

In additional feature, the actuator is configured to move the plasma tuning ring to contact the edge ring after the edge ring is clamped to the substrate support.

In additional feature, the temperature probe moves with the plasma tuning ring when the actuator actuates the plasma tuning ring.

In additional features, the plasma tuning ring comprises an electrode to supply radio frequency power to the edge ring. The actuator is configured to move the plasma tuning ring to maintain coupling between the plasma tuning ring and the edge ring during substrate processing.

In additional features, the temperature probe comprises a temperature sensor attached to an end of the temperature probe that is proximate to the plasma tuning ring. The spring assembly is configured to maintain contact between the temperature sensor and the edge ring.

In additional features, the plasma tuning ring comprises an electrode to supply radio frequency power to the edge ring. The temperature probe passes through the electrode to contact the edge ring.

Further areas of applicability of the present disclosure will become apparent from the detailed description, the claims, and the drawings. The detailed description and specific examples are intended for purposes of illustration only and are not intended to limit the scope of the disclosure.

### BRIEF DESCRIPTION OF THE DRAWINGS

The present disclosure will become more fully understood from the detailed description and the accompanying drawings, wherein:

FIG. 1 shows an example of a substrate processing system comprising a tunable edge sheath (TES) ring actuator employing bellows and a temperature probe employing bellows according to the present disclosure;

FIG. 2 shows a substrate support along with the TES actuator employing the bellows and the temperature probe employing the bellows in further detail;

FIGS. 3 and 4 show the TES actuator and the bellows in further detail; and

FIGS. 5 and 6 show the temperature probe and the bellows in further detail.

In the drawings, reference numbers may be reused to identify similar and/or identical elements.

### DETAILED DESCRIPTION

The top edge ring (TER) is clamped to the substrate support during substrate processing. The tunable edge sheath (TES) ring needs to move down to allow the TER to clamp to the substrate support. After the TER is clamped to the substrate support, the TES ring needs to move up to contact the TER during substrate processing. To move the TES ring up and down, at least three actuation assemblies are used. For example, the three actuation assemblies are spaced 120 degrees apart from each other. Each actuation assembly comprises a rod coupled to an actuator. The three rods, spaced 120 degrees apart from each other, are inserted through the substrate support into the TES ring. The distal ends of the rods are coupled to the respective actuators located under the substrate support. The actuators move the rods, which in turn move the TES ring up and down relative to the TER.

Additionally, to sense the temperature of the TER, at least three temperature probes are inserted through the substrate support and the TES ring. For example, the three temperature probes are also spaced 120 degrees apart from each other and are radially offset from the rods. The temperature probes also need to move clear of the TER to allow the TER to clamp to the substrate support. Additionally, the temperature probes also need to maintain contact with the TER to sense the temperature of the TER during substrate processing. The force used to actuate the temperature probes needs to be sufficient for the temperature probes to contact the TER but not excessive to dislodge the TER.

While the TER, the TES ring, the rods, and the temperature probes are under vacuum in the processing chamber, the actuators are not under vacuum but are at atmospheric pressure. Therefore, O-rings are typically used as static seals around the rods and the temperature probes to maintain the vacuum in the processing chamber. However, the O-rings restrict (i.e., damp) the movements of the rods and the temperature probes. Further, the O-rings deteriorate over time. Consequently, frictional forces between the O-rings and the rods and the temperature probes vary. The variation in the frictional forces complicates controlling the movements of the rods and the temperature probes. The variation in the frictional forces also complicates maintaining the repeatability of the RF coupling between the TES ring and the TER. Further, the variation in the frictional forces complicates determining the amount of force needed to maintain contact between the temperature probes and the TER.

To solve the above problems, the present disclosure uses bellows as a dynamic/moving seal for the rods and the temperature probes. To maintain the vacuum in the processing chamber, O-ring seals are used above and below the bellows but not around the rods and the temperature probes. The O-rings above and below the bellows maintain the vacuum in the processing chamber while the rods and the temperature probes are moved up and down freely through the bellows. The bellows flex up and down like an accordion as the rods and the temperature probes are moved up and down through the bellows. The O-rings above and below the bellows do not surround the rods and the temperature probes. Therefore, the movements of the rods and the temperature probes are not damped by the frictional forces mentioned above.

The bellows operate as seals and not as springs. That is, the bellows do not add or subtract force to the movements of the rods and the temperature probes. The force applied at the bottom of the rods by the respective actuators is almost equal to the force applied by the rod to the TES ring. The force applied at the bottom of the temperature probes by respective compression springs (described below) is almost equal to the force applied by the rod to the TES ring. Accordingly, the movements of the rods and the temperature probes can be accurately controlled with minimal force from the actuators since additional force is not needed to overcome the frictional forces. The coupling between the TER and the TES ring and the temperature probes can be maintained during substrate processing. Additionally, the clamping of the TER is not obstructed by the TES ring and the temperature probes since TES ring and the temperature probes are retracted before the TER clamps.

Thus, the bellows and the O-rings not only maintain the vacuum in the processing chamber but also simplify the actuation and movements of the TES ring and the temperature probes. The flexibility of the bellows helps in maintaining the coupling between the TES ring and the TER while ensuring proper clamping of the TER. The flexibility of the bellows also helps in maintaining the coupling between the temperature probes and the TER while ensuring proper clamping of the TER. Further, the bellows are made of a material such as a polymer (e.g., polytetrafluoroethylene (PTFE)). The material does not erode or deform and does not cause arcing during substrate processing. These and other features of the present disclosure are described below in further detail.

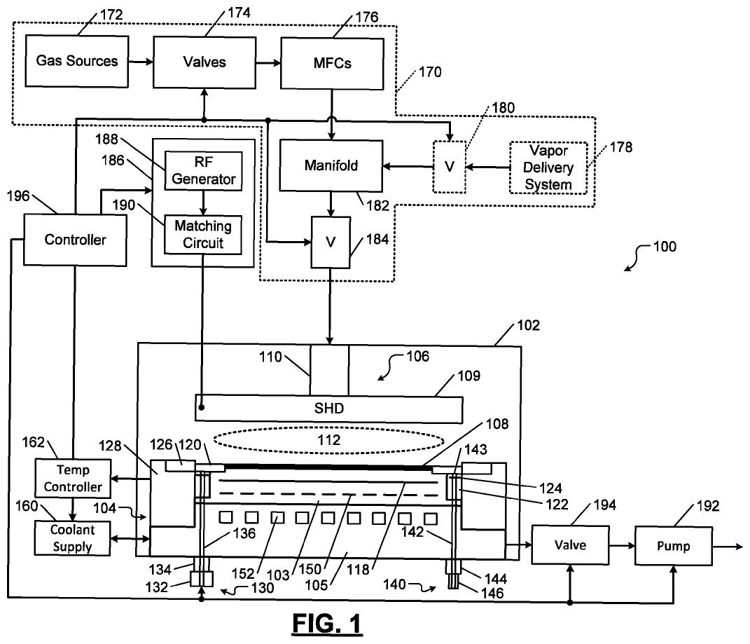

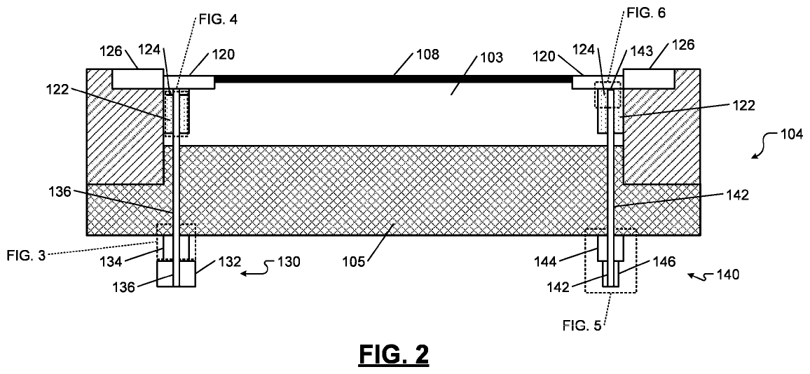

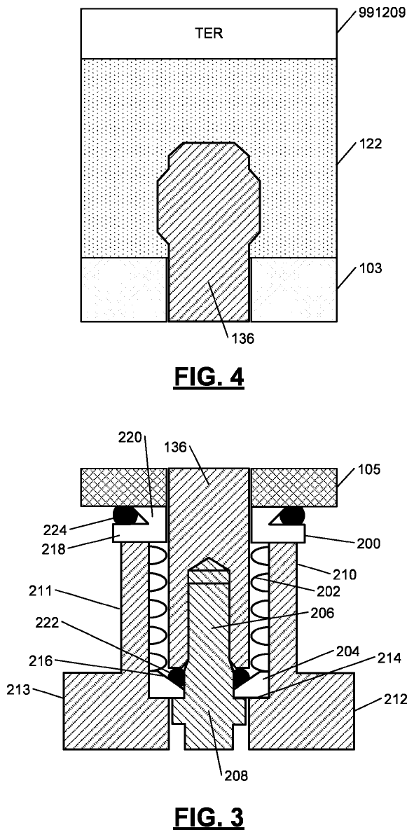

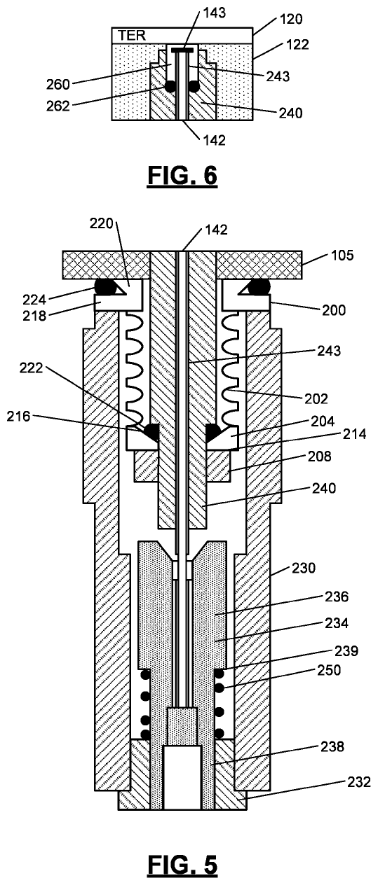

The present disclosure is organized as follows. Initially, an example of a substrate processing system is described using FIG. 1 to illustrate where the bellows are used in the substrate processing system. The TER, the TES ring, the rod and the actuator employing the bellows for the TER, and the temperature probe employing the bellows are shown more clearly in FIG. 2. The bellows used with the actuator for actuating the TES ring are shown and described in further detail in FIGS. 3 and 4. The bellows used with the temperature probe are shown and described in further detail in FIGS. 5 and 6.

### SUBSTRATE PROCESSING SYSTEM

FIG. 1 shows an example of a substrate processing system 100 for processing substrates. The substrate processing system 100 comprises a processing chamber 102 for processing the substrates using processes such as plasma etching. The processing chamber 102 comprises a substrate support 104 and a showerhead 106. For example, the substrate support 104 comprises an electrostatic chuck (ESC) although other types of substrate supports can be used instead. A substrate 108 is arranged on the substrate support 104 during processing.

FIG. 2 separately shows the substrate support 104. In FIG. 2, some of the elements of the substrate support 104 shown in FIG. 1 are omitted to show other elements more clearly. In the following description, reference is made to both FIGS. 1 and 2. FIG. 2 is referenced when describing the other elements that are more clearly visible in FIG. 2 than in FIG. 1.

In FIG. 1, the showerhead 106 comprises a base portion 109 and a stem portion 110. The base portion 109 is generally cylindrical and extends radially outwardly towards sidewalls of the processing chamber 102. The stem portion 110 is also cylindrical and is smaller in diameter than the base portion 109. One end of the stem portion 110 is attached to the center of the base portion 109. The other end of the stem portion 110 is attached to a top plate of the processing chamber 102.

The base portion 109 of the showerhead 106 comprises a plurality of through holes (not shown) on a substrate-facing side of the base portion 109. The showerhead 106 receives one or more gases from a gas delivery system (described below). The gases are dispensed via the through holes in the base portion 109 into the processing chamber 102. A plasma 112 may be struck between the showerhead 106 and the substrate 108 during substrate processing as explained below.

In FIGS. 1 and 2, the substrate support 104 comprises a ceramic plate 103 disposed on a metallic baseplate 105. The ceramic plate 103 comprises an electrode 118 to electrostatically clamp the substrate 108 to the substrate support 104 during substrate processing. A top edge ring (TER) 120 is arranged on the substrate support 104 along a periphery of the substrate support 104. The TER 120 surrounds the substrate 108 as shown. The TER 120 is also electrostatically clamped to the ceramic plate of the substrate support 104 during substrate processing.

A tuning edge sheath (TES) ring 122 is arranged under and adjacent to the TER 120 in the ceramic plate 103 of the substrate support 104. The TES ring 122 comprises an electrode 124 that supplies RF power to the TER 120. The RF power is used to adjust the shape of the plasma 112 near the edge of the substrate 108. The RF power can be adjusted to control etch uniformity on the substrate 108. A plurality of additional edge rings 126, 128 is arranged at the periphery of the substrate support 104.

An actuator assembly 130 is used to actuate the TES ring 122. While only one actuator assembly 130 is shown, at least three actuator assemblies 130 are used to actuate the TES ring 122. For example, the three actuator assemblies 130 are spaced 120 degrees apart from each other around the substrate support 104 and are used to actuate the TES ring 122. The actuator assembly 130 is described below in further detail with reference to FIGS. 3 and 4.

Briefly, the actuator assembly 130 comprises an actuator 132, bellows 134, and a rod 136. The actuator 132 and the bellows 134 are mounted to the bottom of the substrate support 104 (i.e., to the bottom of the processing chamber 102). The bellows 134 are disposed between the actuator 132 and the bottom of the processing chamber 102. One end of the rod 136 is coupled to the actuator 132 through the bellows 134. A distal end of the rod 136 passes through the substrate support 104 and is inserted and fixed into the TES ring 122.

The bellows 134 are shown and described below in detail with reference to FIG. 3. While the TER 120, the TES ring 122, and the rod 136 are in the processing chamber 102 under vacuum, the actuator 132 and the bellows 134 are at atmospheric pressure. Therefore, O-ring seals used above and below the bellows 134 to maintain the vacuum in the processing chamber 102. The O-ring seals are shown and described below in further detail with reference to FIG. 3.

In use, the actuator 132 moves the rod 136 up and down through the bellows 134, which in turn moves the TES ring 122 up and down relative to the TER 120. The bellows 134 flex (e.g., compress and expand) like an accordion when the actuator 132 moves the rod 136 up and down. The actuator 132 and the rod 136 move the TES ring 122 down and the bellows 134 expand when the TER 120 clamps to the substrate support 104. Thus, the TES ring 122 does not obstruct the clamping of the TER 120. During substrate processing, after the TER 120 is clamped, the actuator 132 and the rod 136 move the TES ring 122 up and the bellows 134 compress so that the TES ring 122 contacts the TER 120. During substrate processing, the electrode 124 in the TES ring 122 provides RF power to the TER 120 to adjust the shape of the plasma 112 near the edge of the substrate 108. The RF power can be adjusted to control etch uniformity on the substrate 108.

A temperature sensing assembly 140 is used to measure the temperature of the TES ring 122. While only one temperature sensing assembly 140 is shown, at least three temperature measuring assemblies 140 are arranged around the substrate support 104 and are used to measure the temperature of the TES ring 122. For example, the three temperature measuring assemblies 140 are spaced 120 degrees apart from each other and are radially offset from the three actuator assemblies 130. The temperature sensing assembly 140 is described below in further detail with reference to FIGS. 5 and 6.

Briefly, the temperature sensing assembly 140 comprises a temperature probe 142 and a temperature sensor 143. The temperature sensor 143 is mounted on (i.e., attached to) one end of the temperature probe 142 to sense the temperature of the TES ring 122. The temperature sensing assembly 140 further comprises bellows 144 and a spring assembly 146. The bellows 144 and the spring assembly 146 are mounted to the bottom of the substrate support 104 (i.e., to the bottom of the processing chamber 102). The bellows 144 are disposed between the spring assembly 146 and the bottom of the processing chamber 102. A distal end of the temperature probe 142 passes through the substrate support 104 and the bellows 144 and is coupled to the spring assembly 146.

The bellows 144 and the spring assembly 146 are shown and described below in further detail with reference to FIG. 5. While the temperature probe 142 and the temperature sensor 143 are in the processing chamber 102 under vacuum, the bellows 144 and the spring assembly 146 are at atmospheric pressure. Therefore, O-ring seals are used above and below the bellows 144 to maintain the vacuum in the processing chamber 102. The O-ring seals are shown and described below in further detail with reference to FIG. 5.

In use, when the TES ring 122 is moved up and down, the temperature probe 142 also moves up and down freely through the bellows 144 as described below in detail with reference to FIG. 5. The bellows 144 flex (e.g., compress and expand) like an accordion when the temperature probe 142 moves up and down. Thus, the temperature probe 142 does not obstruct the clamping of the TER 120. Additionally, when the TES ring 122 is moved up and down, the spring assembly 146 provides the force needed for the temperature sensor 143 to maintain contact with the TER 120 as described below in detail with reference to FIGS. 5 and 6. Thus, the temperature of the TER 120 can be accurately sensed.

In FIG. 1, the substrate support 104 further comprises a heater 150 and cooling channels 152. The heater 150 is arranged under the electrode 118 in the ceramic plate 103 of the substrate support 104. The heater 150 heats the substrate 108 during substrate processing. The cooling channels 152 are disposed in the baseplate 105 of the substrate support 104. A coolant supply 160 circulates a coolant through the cooling channels 152 to control the temperature of the substrate support 104 and the substrate 108 during substrate processing.

A temperature controller 162 receives the temperature of the substrate support 104 from temperature sensors (not shown) disposed in the substrate support 104. The temperature controller 162 also receives the temperature of the TER 120 from the temperature sensors 144 of the temperature measuring assemblies 140. Based on the temperatures of the substrate support 104 and the TER 120, the temperature controller 162 controls the heater 150 and the supply of the coolant from the coolant supply 160 through the cooling channels 152.

The substrate processing system 100 further comprises a gas delivery system 170 to supply various gases (e.g., process gases, purge gases, cleaning gases, etc.) to the processing chamber 102. The gas delivery system 170 comprises gas sources 172, valves 174, and mass flow controllers (MFCs) 176. The gas sources 172 supply the various gases through the valves 174 to the MFCs 176. The MFCs 176 control the flow rates of the gases. The MFCs 176 supply the gases at the controlled flow rates to a mixing manifold 182.

In addition, the gas delivery system 170 comprises a vapor delivery system 178 to deliver one or more vaporized precursors used in some processes. The vapor delivery system 178 delivers the vaporized precursors through valves 180 to the mixing manifold 182. The gases (or gas mixtures) from the mixing manifold 182 are delivered to the showerhead 106 via a valve system 184 attached to the showerhead 106.

The substrate processing system 100 further comprises a RF power supply 186 that supplies RF power to the showerhead 106 to generate the plasma 112 during substrate processing. The RF power supply 186 comprises an RF generator 188 and a matching circuit 190. The RF generator 188 generates the RF power. The matching circuit 190 performs impedance matching and outputs the RF power to the showerhead 106. When the process gases are supplied to the showerhead 106, the RF power supply 186 supplies the RF power to the showerhead 106 to generate the plasma 112.

The substrate processing system 100 further comprises a vacuum pump 192 that is connected to the processing chamber 102 via a valve 194. The vacuum pump 192 maintains vacuum in the processing chamber 102. The vacuum pump 192 also evacuates reactants from the processing chamber 102. The substrate processing system 100 further comprises a controller 196. The controller 196 controls the operations of all of the components of the substrate processing system 100 described above and below.

### TES Actuator Assembly

FIGS. 3 and 4 show the actuator assembly 130 in further detail. FIG. 3 shows a lower portion of the actuator assembly 130. FIG. 4 shows an upper portion of the actuator assembly 130. FIG. 3 shows a cross-sectional view of the bellows 134. FIG. 4 shows a cross-sectional view of the rod 136 and the TES ring 122.

In FIG. 3, the bellows 134 comprise elements 200, 202, and 204. The elements 200, 202, and 204 are made of a polymer (e.g., polytetrafluoroethylene (PTFE)). The material does not erode or deform and does not cause arcing during substrate processing in the processing chamber 102. The elements 200, 202, and 204 of the bellows 134 are not separate elements but are manufactured as a single, integrated, monolithic structure. The element 202 is flexible and extends between the elements 200 and 204. The element 202 expands and compresses like an accordion. The elements 200 and 204 are described below in further detail.

The bellows 134 are generally cylindrical in shape with a hollow volume along the center through which the rod 136 passes. The rod 136 is coupled to the actuator 132 (shown in FIGS. 1 and 2) by a shaft (also called a peek rod) 206. The shaft 206 is inserted centrally into the rod 136 through a lower end of the rod 136. A nut 208 at a lower end of the shaft 206 secures the shaft 206 to the rod 136. A lower end of the shaft 206 is connected to the actuator 132.

The bellows 134 are encased in a hollow cylindrical casing 210. The casing 210 can be made of a plastic material or another type of material. The casing 210 comprises a vertical portion 211 and a base portion 213. The vertical portion 211 surrounds the element 202. A top end of the vertical portion 211 is attached to a bottom of the element 200. A bottom end of the vertical portion 211 is attached to radially outer and bottom portions of the element 204 of the bellows 134 and to the base portion 213 of the casing 210. The base portion 213 is greater in diameter than the vertical portion 211 and forms a flange 212 that extends radially outwards. The flange 212 is attached to a body of the actuator 132 (shown in FIGS. 1 and 2).

The element 204 of the bellows 134 comprises a flat portion 214 at the bottom of the element 204 and a wedge-shaped portion 216 on an inner side of the element 204. The flat portion 214 rests on the nut 208. The wedge-shaped portion 216 tapers from the top of the element 204 radially inwards towards the bottom flat portion 214.

The element 200 of the bellows 134 comprises a flat portion 218 at the bottom of the element 200. The element 200 of the bellows 134 comprises a wedge-shaped portion 220 on an outer side of the element 200. The flat portion 218 of the element 200 rests on a top end of the vertical portion 211 of the casing 210. The wedge-shaped portion 220 tapers radially outwards from the top of the flat portion 218. A top end of the wedge-shaped portion 220 is flat. The top end of the wedge-shaped portion 220 is attached to the bottom of the baseplate 105 of the substrate support 104 (i.e., to the bottom of the processing chamber 102).

An O-ring 222 is disposed around the wedge-shaped portion 216 of the element 204. An O-ring 224 is disposed around the wedge-shaped portion 220 of the element 200. The O-rings 222 and 224 provide a seal that maintains the vacuum in the processing chamber 102 while the actuator 132 moves the rod 136 up and down freely through the element 202. The O-rings 222 and 224 do not surround the rod 136 and therefore do not drag the rod 136.

The element 202 flexes up and down like an accordion as the actuator 132 moves the rod 136 up and down freely through the element 202 to move the TES ring 122 before and after the clamping of the TER 120. Therefore, the movement of the rod 136 is not damped by frictional forces. The actuator 132 can accurately control the movement of the rod 136 with minimal force since additional force is not needed to overcome the frictional forces. The coupling between the TER 120 and the TES ring 122 can be maintained during substrate processing. Additionally, the clamping of the TER 120 is not obstructed by the TES ring 122. Thus, the bellows 134 and the O-rings 222 and 224 not only maintain the vacuum in the processing chamber 102 but also simplify the actuation and movement of the TES ring 122. The flexibility of the element 202 helps in maintaining the coupling between the TES ring 122 and the TER 120 while ensuring proper clamping of the TER 120.

FIG. 4 shows the coupling between the rod 136 and the TES ring 122 in further detail. The top end of the rod 136 is flared radially outwards as shown. Alternatively, the top end of the rod 136 can comprise a flange that extends radially outwards. The structure of the top end of the rod 136 is such that the top end of the rod 136 is securely attached to the TES ring 122. Thus, the top end of the rod 136 can accurately move the TES ring 122 vertically up and down relative to the TER 120 when the actuator 132 actuates the rod 136 in a controlled manner. The accurate movement of the TES ring 122 ensures that the TES ring 122 does not obstruct the TER 120 when the TER 120 is clamped to the substrate support 104. Additionally, the accurate movement of the TES ring 122 ensures the coupling between the TES ring 122 and the TER 120 during substrate processing.

### Temperature Sensing Assembly

FIGS. 5 and 6 show the temperature sensing assembly 140 in detail. FIG. 5 shows a cross-sectional view of a lower portion of the temperature sensing assembly 140. FIG. 6 shows a cross-sectional view of an upper portion of the temperature sensing assembly 140.

In FIG. 5, similar to the bellows 134, the bellows 144 comprise the elements 200, 202, and 204. While some of the following description of the bellows 144 is similar to the description of the bellows 134, the bellows 144 are described again in detail for clarity since the structure of the temperature sensing assembly 140 differs from the structure of the actuator assembly 130.

Similar to the bellows 134, the elements 200, 202, and 204 are made of a polymer (e.g., polytetrafluoroethylene (PTFE)). The material does not erode or deform and does not cause arcing during substrate processing in the processing chamber 102. Similar to the bellows 134, the elements 200, 202, and 204 of the bellows 144 are manufactured as a single, integrated, monolithic structure.

The bellows 144 comprise the element 202 that extends between the elements 200 and 204. The element 202 expands and compresses like an accordion. The bellows 144 are generally cylindrical in shape with a hollow volume along the center through which the temperature probe 142 passes. The bellows 144 are encased in a hollow cylindrical casing 230. The casing 230 can be made of a plastic material or another type of material. The casing 230 is described below in further detail.

The element 204 of the bellows 144 comprises the flat portion 214 at the bottom of the element 204 and the wedge-shaped portion 216 on the inner side of the element 204. The flat portion 214 rests on the nut 208. The wedge-shaped portion 216 tapers from the top of the element 204 radially inwards towards the bottom flat portion 214.

The element 200 of the bellows 144 comprises the flat portion 218 at the bottom of the element 200. The element 200 of the bellows 134 comprises the wedge-shaped portion 220 on the outer side of the element 200. The flat portion 218 of the element 200 rests on a top end of the casing 230. The wedge-shaped portion 220 tapers radially outwards from the top of the flat portion 218. The top end of the wedge-shaped portion 220 is flat. The top end of the wedge-shaped portion 220 is attached to the bottom of the baseplate 105 of the substrate support 104 (i.e., to the bottom of the processing chamber 102).

The casing 230 surrounds the bellows 144 and the spring assembly 146. The spring assembly 146 comprises a spring 250 and a holder 234. For example, the spring 250 is a compression type spring. The spring 250 is wound around the holder 234. A flanged ring or a nut 232 is inserted into a bottom end of the casing 230. The holder 234 is inserted centrally through the nut 232 into a central hollow region of the casing 230. The holder 234 extends through the hollow region of the casing 230 towards the nut 208. A lower portion of the temperature probe 142 passes through the holder 234. The holder 234 holds the lower portion of the temperature probe 142.

The holder 234 is cylindrical and comprises an upper portion 236 and a lower portion 238. The upper portion 236 has a greater diameter than the lower portion 238. Thus, a flange 239 is formed at a joint of the upper and lower portions 236, 238. The outer diameter of the upper portion 236 is less than an inner diameter of the casing 230. The upper and lower portions 236, 238 are not separate elements. Instead, the upper and lower portions 236, 238 are manufactured as an integrated single piece, and the holder 234 is monolithic. The spring 250 is held between the nut 232 and the flange 239. The spring 250 expands and compresses between the nut 232 and the flange 239 when the holder 234 moves up and down as the temperature probe 142 moves up and down with the TES ring 122.

In some types of temperature probes, a conduit 243 is disposed from near a top end of the holder 234 through the bellows 144 and the substrate support 104. The conduit 243 extends up to the top of the TES ring 122. The temperature probe 142 passes through the conduit 243. A sealant 240 is disposed around the conduit 243 in the hollow volume between the conduit 243 and the bellows 144. For example, the sealant 240 comprises an epoxy material. The nut 208 at the bottom of the element 204 of the bellows 144 is secured to the sealant 240. The sealant 240 extends downwards below the bellows 144 and below the nut 208 towards the top end of the holder 234. The sealant 240 extends upwards through the bellows 144 and the substrate support 104 around the conduit 243 up to the top of the TES ring 122 (see FIG. 6). The sealant 240 provides a seal against the vacuum used in the processing chamber 102.

The spring 250 is disposed between the flange 239 of the holder 234 and an upper end of the nut 232. The spring 250 surrounds the lower portion 236 of the holder 234. When the TES ring 122 is moved downwards before the clamping of the TER 120, the temperature probe 142 and the holder 234 push (i.e., compress) the spring 250 downwards so that the temperature sensor 143 does not obstruct the clamping of the TER 120. After the TER 120 is clamped, as the TES ring 122 is moved upwards to contact the TER 120, the spring 250 expands and pushes the holder 234 and the temperature probe 142 upwards so that the temperature sensor 143 contacts the TER 120 during substrate processing (see FIG. 6).

The element 202 of the bellows 144 flexes up and down like an accordion as the holder 234 and the temperature probe 142 move up and down freely under the control of the spring 250 before and after the clamping of the TER 120. Therefore, the movement of the temperature probe 142 is not damped by frictional forces. The spring 250 can accurately control the movement of the temperature probe 142 with minimal force since additional force is not needed to overcome the frictional forces. The contact between the temperature probe 142 and the TER 120 can be maintained during substrate processing. Additionally, the temperature probe 142, which moves freely through the bellows 144 under the control of the spring 250, does not obstruct the clamping of the TER 120.

Thus, the bellows 144 and the O-rings 222 and 224 not only maintain the vacuum in the processing chamber 102 but also simplify the movement of the temperature probe 142. As the TES ring 122 is moved up and down, the flexibility of the element 202 and the force of the spring 250 help in maintaining contact between the temperature sensor 143 and the TER 120 while ensuring proper clamping of the TER 120 without obstruction from the temperature probe 142.

The O-ring 222 is disposed around the wedge-shaped portion 216 of the element 204. The O-ring 224 is disposed around the wedge-shaped portion 220 of the element 200. The O-rings 222 and 224 and the sealant 240 provide a seal that maintains the vacuum in the processing chamber 102 while the temperature probe 142 moves up and down freely through the element 202. The O-rings 222 and 224 do not surround the temperature probe 142 and therefore do not drag (i.e., do not impede) the movement of the temperature probe 142 or the sealant 240 surrounding the temperature probe 142.

FIG. 6 shows the coupling between the temperature probe 142 and the TES ring 122 in further detail. The electrode 124 in the TES ring 122 is omitted to simplify illustration of other elements. As shown in FIGS. 1 and 2, the temperature probe 142 passes through an aperture in the electrode 124 towards TER 120. A cavity 260 exists between the conduit 243 of the temperature probe 142 and the sealant 240 near the top end of the temperature probe 142 where the temperature sensor 143 is mounted to the temperature probe 142. An O-ring 262 is disposed in the cavity 260 around the conduit 243. The O-ring 262 prevents erosion within the temperature probe 142 from the chemistries used in the processing chamber 102. The O-ring 262 also prevents erosion of the sealant 240 from the chemistries used in the processing chamber 102. The O-ring 262 does not drag (i.e., does not impede) the movement of the temperature probe 142.

The foregoing description is merely illustrative in nature and is not intended to limit the disclosure, its application, or uses. The broad teachings of the disclosure can be implemented in a variety of forms. Therefore, while this disclosure includes particular examples, the true scope of the disclosure should not be so limited since other modifications will become apparent upon a study of the drawings, the specification, and the following claims.

It should be understood that one or more steps within a method may be executed in different order (or concurrently) without altering the principles of the present disclosure. Further, although each of the embodiments is described above as having certain features, any one or more of those features described with respect to any embodiment of the disclosure can be implemented in and/or combined with features of any of the other embodiments, even if that combination is not explicitly described. In other words, the described embodiments are not mutually exclusive, and permutations of one or more embodiments with one another remain within the scope of this disclosure.

Spatial and functional relationships between elements (for example, between modules, circuit elements, semiconductor layers, etc.) are described using various terms, including “connected,” “engaged,” “coupled,” “adjacent,” “next to,” “on top of,” “above,” “below,” and “disposed.” Unless explicitly described as being “direct,” when a relationship between first and second elements is described in the above disclosure, that relationship can be a direct relationship where no other intervening elements are present between the first and second elements, but can also be an indirect relationship where one or more intervening elements are present (either spatially or functionally) between the first and second elements. As used herein, the phrase at least one of A, B, and C should be construed to mean a logical (A OR B OR C), using a non-exclusive logical OR, and should not be construed to mean “at least one of A, at least one of B, and at least one of C.”

In some implementations, a controller is part of a system, which may be part of the above-described examples. Such systems can comprise semiconductor processing equipment, including a processing tool or tools, chamber or chambers, a platform or platforms for processing, and/or specific processing components (a wafer pedestal, a gas flow system, etc.). These systems may be integrated with electronics for controlling their operation before, during, and after processing of a semiconductor wafer or substrate. The electronics may be referred to as the “controller,” which may control various components or subparts of the system or systems.

The controller, depending on the processing requirements and/or the type of system, may be programmed to control any of the processes disclosed herein, including the delivery of processing gases, temperature settings (e.g., heating and/or cooling), pressure settings, vacuum settings, power settings, radio frequency (RF) generator settings, RF matching circuit settings, frequency settings, flow rate settings, fluid delivery settings, positional and operation settings, wafer transfers into and out of a tool and other transfer tools and/or load locks connected to or interfaced with a specific system.

Broadly speaking, the controller may be defined as electronics having various integrated circuits, logic, memory, and/or software that receive instructions, issue instructions, control operation, enable cleaning operations, enable endpoint measurements, and the like. The integrated circuits may include chips in the form of firmware that store program instructions, digital signal processors (DSPs), chips defined as application specific integrated circuits (ASICs), and/or one or more microprocessors, or microcontrollers that execute program instructions (e.g., software).

Program instructions may be instructions communicated to the controller in the form of various individual settings (or program files), defining operational parameters for carrying out a particular process on or for a semiconductor wafer or to a system. The operational parameters may, in some embodiments, be part of a recipe defined by process engineers to accomplish one or more processing steps during the fabrication of one or more layers, materials, metals, oxides, silicon, silicon dioxide, surfaces, circuits, and/or dies of a wafer.

The controller, in some implementations, may be a part of or coupled to a computer that is integrated with the system, coupled to the system, otherwise networked to the system, or a combination thereof. For example, the controller may be in the “cloud” or all or a part of a fab host computer system, which can allow for remote access of the wafer processing. The computer may enable remote access to the system to monitor current progress of fabrication operations, examine a history of past fabrication operations, examine trends or performance metrics from a plurality of fabrication operations, to change parameters of current processing, to set processing steps to follow a current processing, or to start a new process.

In some examples, a remote computer (e.g. a server) can provide process recipes to a system over a network, which may include a local network or the Internet. The remote computer may include a user interface that enables entry or programming of parameters and/or settings, which are then communicated to the system from the remote computer. In some examples, the controller receives instructions in the form of data, which specify parameters for each of the processing steps to be performed during one or more operations. It should be understood that the parameters may be specific to the type of process to be performed and the type of tool that the controller is configured to interface with or control.

Thus, as described above, the controller may be distributed, such as by comprising one or more discrete controllers that are networked together and working towards a common purpose, such as the processes and controls described herein. An example of a distributed controller for such purposes would be one or more integrated circuits on a chamber in communication with one or more integrated circuits located remotely (such as at the platform level or as part of a remote computer) that combine to control a process on the chamber.

Without limitation, example systems may include a plasma etch chamber or module, a deposition chamber or module, a spin-rinse chamber or module, a metal plating chamber or module, a clean chamber or module, a bevel edge etch chamber or module, a physical vapor deposition (PVD) chamber or module, a chemical vapor deposition (CVD) chamber or module, an atomic layer deposition (ALD) chamber or module, an atomic layer etch (ALE) chamber or module, an ion implantation chamber or module, a track chamber or module, and any other semiconductor processing systems that may be associated or used in the fabrication and/or manufacturing of semiconductor wafers.

As noted above, depending on the process step or steps to be performed by the tool, the controller might communicate with one or more of other tool circuits or modules, other tool components, cluster tools, other tool interfaces, adjacent tools, neighboring tools, tools located throughout a factory, a main computer, another controller, or tools used in material transport that bring containers of wafers to and from tool locations and/or load ports in a semiconductor manufacturing factory.

What is claimed is:

1. An actuator assembly to actuate a plasma tuning ring in a processing chamber, the actuator assembly comprising:
an actuator arranged external to the processing chamber, the processing chamber being under vacuum, and the actuator being at atmospheric pressure;
a rod coupled to the actuator and to the plasma tuning ring in the processing chamber;
bellows arranged external to the processing chamber between the actuator and the processing chamber, the rod passing through the bellows into the processing chamber; and
vacuum seals disposed between the bellows and the actuator and between the bellows and the processing chamber to seal the vacuum in the processing chamber from the atmospheric pressure external to the processing chamber.

2. The actuator assembly of claim 1 wherein the bellows comprise a polymer.

3. The actuator assembly of claim 1 wherein the vacuum seals do not obstruct movement of the rod through the bellows.

4. The actuator assembly of claim 1 wherein the vacuum seals comprise O-rings.

5. A system comprising the actuator assembly of claim 1 and further comprising:
a substrate support arranged in the processing chamber to support a substrate, wherein the plasma tuning ring is arranged in the substrate support;
an edge ring arranged proximate to the plasma tuning ring and around the substrate during substrate processing; and
a temperature sensing assembly to sense temperature of the edge ring, the temperature sensing assembly comprising:
a spring assembly arranged external to the processing chamber;
second bellows arranged external to the processing chamber between the spring assembly and the processing chamber; and
a temperature probe coupled to the spring assembly, the temperature probe passing through the second bellows and the plasma tuning ring, the spring assembly maintaining contact between the temperature probe and the edge ring.

6. The system of claim 5 wherein the second bellows comprise a polymer.

7. The system of claim 5 further comprising second vacuum seals disposed between the second bellows and the spring assembly and between the second bellows and the processing chamber to seal the vacuum in the processing chamber.

8. The system of claim 7 wherein the second vacuum seals do not obstruct movement of the temperature probe through the second bellows.

9. The system of claim 7 wherein the second vacuum seals comprise O-rings.

10. The system of claim 5 wherein the actuator is configured to move the plasma tuning ring away from the edge ring when the edge ring clamps to the substrate support.

11. The system of claim 5 wherein the actuator is configured to move the plasma tuning ring to contact the edge ring after the edge ring is clamped to the substrate support.

12. The system of claim 5 wherein the temperature probe moves with the plasma tuning ring when the actuator actuates the plasma tuning ring.

13. The system of claim 5 wherein the plasma tuning ring comprises an electrode to supply radio frequency power to the edge ring and wherein the actuator is configured to move the plasma tuning ring to maintain coupling between the plasma tuning ring and the edge ring during substrate processing.

14. The system of claim 5 wherein the temperature probe comprises a temperature sensor attached to an end of the temperature probe that is proximate to the plasma tuning ring and wherein the spring assembly is configured to maintain contact between the temperature sensor and the edge ring.

15. The system of claim 5 wherein the plasma tuning ring comprises an electrode to supply radio frequency power to the edge ring and wherein the temperature probe passes through the electrode to contact the edge ring.

16. The system of claim 5 wherein:
the spring assembly comprises a spring disposed around a holder, the temperature probe passing through the holder; and
a sealant disposed around the temperature probe, the sealant extending from the holder through the second bellows, the substrate support, and the plasma tuning ring to seal the vacuum in the processing chamber.

17. The system of claim 16 wherein the sealant comprises an epoxy material.

18. The system of claim 16 wherein the temperature sensing assembly further comprises a second seal disposed around the temperature probe in the plasma tuning ring to prevent erosion of the temperature probe and the sealant.

19. The system of claim 18 wherein the second seal comprises an O-ring.

20. A system comprising:
a substrate support arranged in a processing chamber under vacuum to support a substrate;
an edge ring arranged around the substrate on the substrate support;
a plasma tuning ring arranged adjacent to the edge ring in the substrate support; and
an actuator assembly to actuate the plasma tuning ring, the actuator assembly comprising:
an actuator coupled externally to the processing chamber, the actuator being at atmospheric pressure;
a rod coupled to the actuator and to the plasma tuning ring;
bellows arranged externally to the processing chamber between the actuator and the processing chamber, the rod passing through the bellows; and
vacuum seals disposed between the bellows and the actuator and between the bellows and the processing chamber to seal the vacuum in the processing chamber from the atmospheric pressure external to the processing chamber.

21. The system of claim 20 wherein the vacuum seals do not obstruct movement of the rod through the bellows.

22. The system of claim 20 further comprising a temperature sensing assembly comprising:
a spring assembly coupled externally to the processing chamber;
second bellows arranged externally to the processing chamber between the spring assembly and the processing chamber; and
a temperature probe coupled to the spring assembly, the temperature probe passing through the second bellows and the plasma tuning ring, the spring assembly maintaining contact between the temperature probe and the edge ring.

23. The system of claim 22 further comprising second vacuum seals disposed between the second bellows and the spring assembly and between the second bellows and the processing chamber to seal the vacuum in the processing chamber.

24. The system of claim 23 wherein the second vacuum seals do not obstruct movement of the temperature probe through the second bellows.

25. The system of claim 20 wherein the actuator is configured to move the plasma tuning ring away from the edge ring when the edge ring clamps to the substrate support.

26. The system of claim 20 wherein the actuator is configured to move the plasma tuning ring to contact the edge ring after the edge ring is clamped to the substrate support.

27. The system of claim 22 wherein the temperature probe moves with the plasma tuning ring when the actuator actuates the plasma tuning ring.

28. The system of claim 20 wherein the plasma tuning ring comprises an electrode to supply radio frequency power to the edge ring and wherein the actuator is configured to move the plasma tuning ring to maintain coupling between the plasma tuning ring and the edge ring during substrate processing.

29. The system of claim 22 wherein the temperature probe comprises a temperature sensor attached to an end of the temperature probe that is proximate to the plasma tuning ring and wherein the spring assembly is configured to maintain contact between the temperature sensor and the edge ring.

30. The system of claim 22 wherein the plasma tuning ring comprises an electrode to supply radio frequency power to the edge ring and wherein the temperature probe passes through the electrode to contact the edge ring.
